(19) United States
(12) Patent Application Publication
(10) Pub. No.: US 2013/0028445 A1
(43) Pub. Date: Jan. 31, 2013

(54) METHOD FOR PROCESSING AUDIO SIGNAL AND AUDIO SIGNAL OUTPUT APPARATUS ADOPTING THE SAME

(71) Applicants: Jae-cheol LEE, Yongin-si (KR); Jong-woo KIM, Yongin-si (KR); Byung-soo KIM, Seoul (KR); Ki-don HONG, Yongin-si (KR)

(72) Inventors: Jae-cheol LEE, Yongin-si (KR); Jong-woo KIM, Yongin-si (KR); Byung-soo KIM, Seoul (KR); Ki-don HONG, Yongin-si (KR)

(73) Assignee: SAMSUNG ELECTRONICS CO., LTD., Suwon-si (KR)

(21) Appl. No.: 13/554,408

(22) Filed: Jul. 20, 2012

(30) Foreign Application Priority Data
Jul. 27, 2011 (KR) 10-2011-0074760

(51) Int. Cl. H03G 3/00

(52) U.S. Cl. 381/107

(57) ABSTRACT

An audio signal output apparatus and a method for processing an audio signal thereof are provided. the audio signal output apparatus including: an amplification unit receiving and amplifying which receives and amplifies an audio signal; a plurality of comparison units repeatedly comparing which performs comparisons of input levels of the audio signal using with different threshold values; and a control unit controlling which controls an output of the audio signal through by changing of gains a gain of the amplification unit units in accordance with the results of comparison the comparisons performed by the plurality of comparison units.

### CROSS-REFERENCE TO RELATED APPLICATION

This application claims priority under 35 U.S.C. §119(a) from Korean Patent Application No. 10-2011-0074760, filed on Jul. 27, 2011, in the Korean Intellectual Property Office, the disclosure of which is incorporated herein by reference.

### BACKGROUND

1. Field

Apparatuses and methods consistent with the present inventive concept relate to a method for processing an audio signal and an audio signal output apparatus adopting the same, and more particularly to a method for processing an audio signal and an audio signal output apparatus adopting the same, which can limit an excessive output of the audio signal output apparatus through an automatic gain control and thus can protect the audio signal output apparatus.

2. Description of the Related Art

An audio signal output apparatus limits an output of an audio signal using automatic gain control or an auto gain limiter (hereinafter referred to as “auto gain control”). Auto gain control is performed to limit such excessive output of the audio signal that an audio signal output system is unable to reproduce. Auto gain control thus serves to protect an amplifier, as well as to prevent distortion of the audio signal output from the audio signal output system.

Specifically, in order to prevent the output of an audio signal of an excessive level that the audio signal output system cannot reproduce, the audio signal output apparatus controls a gain of an input audio signal through an amplifier so that the audio signal output apparatus can output the audio signal having a level that the audio signal output system can reproduce.

However, even if an audio signal having a level that is lower than a preset threshold value continues to be output over a specified time, the audio signal output apparatus may deteriorate or a speaker may be damaged.

### SUMMARY

Exemplary embodiments address at least the above problems and/or disadvantages and other disadvantages not described above. However, an exemplary embodiment is not required to overcome the disadvantages described above, and an exemplary embodiment may not overcome any of the problems described above.

An aspect of an exemplary embodiment provides an audio signal output apparatus including: an amplification unit which receives and amplifies an audio signal; a plurality of comparison units which performs comparisons of input levels of the audio signal with different threshold values; and a control unit which controls an output of the audio signal by changing a gain of the amplification unit in accordance with results of the comparisons performed by the plurality of comparison units.

The amplification unit may include a plurality of amplifiers, which are equal in number to a number of the comparison units having the different threshold values, and wherein the control unit may adjust gains of each of the plurality of amplifiers in accordance with results of the comparisons performed by the plurality of comparison units.

The amplification unit may include: a first amplifier which amplifies the audio signal; and a second amplifier connected in series to the first amplifier, wherein the plurality of comparison units include: a first comparison unit which performs a comparison of an input level of the audio signal, which is input to the first amplifier, with a first threshold value; and a second comparison unit which performs a comparison of an output level of the first amplifier, with a second threshold value, wherein the control unit adjusts a gain of the first amplifier in accordance with a result of the comparison performed by the first comparison unit and adjusts a gain of the second amplifier in accordance with a result of the comparison performed by the second comparison unit.

The control unit may adjust the gain of the first amplifier so as to reduce the output level of the first amplifier if the input level of the audio signal input to the first amplifier exceeds the first threshold value, and may adjust the gain of the first amplifier so as to maintain the output level of the first amplifier if the input level of the audio signal input to the first amplifier is equal to or lower than the first threshold value, and wherein the control unit may control the second comparison unit to compare the output level of the first amplifier with the second threshold value for a preset time.

The control unit may adjust the gain of the second amplifier so as to reduce an output level of the second amplifier if the output level of the first amplifier exceeds the second threshold value for the preset time, and may adjust the gain of the second amplifier so as to maintain the output level of the first amplifier if the output level of the first amplifier is equal to or lower than the second threshold value.

Each of the plurality of comparison units may include: a first comparison unit which compares an input level of the audio signal, which is input to the amplification unit, with a first threshold value; and a second comparison unit, which is connected in parallel to the first comparison unit, and which compares the input level of the audio signal input to the amplification unit with a second threshold value.

The control unit may adjusts the gain of the amplification unit so as to reduce an output level of the amplification unit if the input level of the audio signal input to the amplification unit exceeds the first threshold value, and may adjust the gain of the amplification unit so as to maintain the output level of the amplification unit if the input level of the audio signal input to the amplification unit is equal to or lower than the first threshold value, and wherein the control unit may control the second comparison unit to compare the output level of the amplification unit with the second threshold value for a preset time.

The control unit may adjust the gain of the amplification unit so as to reduce the output level of the amplification unit if the input level of the audio signal input to the amplification unit exceeds the second threshold value for the preset time, and may adjust the gain of the amplification unit so as to maintain the output level of the amplification unit if the input level of the audio signal input to the amplification unit is equal to or lower than the second threshold value.

The first threshold value may be an output value of the audio signal for which a first error occurs in the audio signal output apparatus if the audio signal having the first threshold value is output, and wherein the second threshold value may be an output value of the audio signal for which a second error occurs in the audio signal output apparatus if the audio signal having the second threshold value is output for a preset time.

An aspect of an exemplary embodiment provides a method for processing an audio signal of an audio signal output apparatus, the method including: comparing a first input level of an audio signal, which is input to a first amplifier included in the audio signal output apparatus, with a first threshold value; comparing a second input level of the audio signal, which is input to a second amplifier included in the audio signal output apparatus, with a second threshold value for a first preset time; and outputting the audio signal by adjusting a gain of one of the first amplifier and the second amplifier based on the comparing of the first input level of an audio signal with the first threshold value and the second input level of the audio signal with the second threshold value.

The outputting of the audio signal may include adjusting the gain of the first amplifier so as to reduce an output level of the first amplifier if the first input level of the audio signal input to the first amplifier exceeds the first threshold value, and adjusting the gain of the first amplifier so as to maintain the output level of the first amplifier if the first input level of the audio signal input to the first amplifier is equal to or lower than the first threshold value.

The outputting of the audio signal may include adjusting the gain of the second amplifier so as to reduce an output level of the second amplifier if the second input level of the audio signal input to the second amplifier exceeds the second threshold value for the first preset time, and adjusting the gain of the second amplifier so as to maintain the output level of the second amplifier if the second input level of the audio signal input to the second amplifier is equal to or lower than the second threshold value.

The method may further include comparing a third input level of the audio signal, which is input to a third amplifier included in the audio signal output apparatus, with a third threshold value for a second preset time; wherein the outputting of the audio signal may include adjusting a gain of the third amplifier so as to reduce an output level of the third amplifier if the third input level of the audio signal input to the third amplifier exceeds the third threshold value for the second preset time, and adjusting the gain of the third amplifier so as to maintain the output level of the third amplifier if the third input level of the audio signal input to the third amplifier is equal to or lower than the third threshold value.

The first threshold value may be a first output value of the audio signal for which a first error occurs in the audio signal output apparatus if the audio signal having the first threshold value is output, and wherein the second threshold value may be a second output value of the audio signal for which a second error occurs in the audio signal output apparatus if the audio signal having the second threshold value is output for a preset time.

An aspect of an exemplary embodiment provides an audio signal output apparatus including: an amplification unit comprising m amplifiers which respectively receive and amplify an input audio signal; a comparison unit comprising n comparators which respectively perform comparisons of input levels of the input audio signal with different threshold values; and a control unit which controls an output of the input audio signal by controlling a change of a gain of the amplification unit in accordance with results of the comparisons performed by the n comparators, wherein m is an integer that is equal to or greater than 1, and n is an integer that is equal to or greater than 2.

Wherein m may equal 1, and wherein the n comparison units may be connected in parallel to each other and may receive the input audio signal as input, and wherein the control unit may adjust the gain of the amplification unit in accordance with the results of the comparisons performed by the n comparison units.

Wherein m may be greater than or equal to 2, wherein the n comparators of the comparison unit may be respectively connected to the m amplifiers of the amplification unit and respectively receive the input audio signal, wherein a second comparator may receive an output signal of an amplifier connected to a first comparator and compares an input level of the received input audio signal with the different threshold values, and wherein the control unit may adjust gains of the respective amplifiers in accordance with the results of the comparisons by the comparators of the comparison unit, including the comparing performed by the second comparator.

An aspect of an exemplary embodiment provides an audio signal output apparatus including: at least one amplification unit which receives and amplifies an input audio signal; a first comparison unit which compares a first input audio signal with a first threshold value; a second comparison unit which compares a second input audio signal with a second threshold value and a preset time; and a control unit which changes a gain of the at least one amplification unit based on at least one of the comparing performed by the first comparison unit and the comparing performed by the second comparison unit.

The first input audio signal may be the second input audio signal.

The comparison units may be connected in parallel.

### BRIEF DESCRIPTION OF THE DRAWINGS

The above and other aspects will be more apparent from the following detailed description when taken in conjunction with the accompanying drawings, in which:

FIG. 1 is a block diagram illustrating the configuration of an audio signal output apparatus according to an exemplary embodiment;

FIG. 2 is a block diagram illustrating the configuration of an auto gain control unit included in the audio signal output apparatus according to an exemplary embodiment;

FIG. 3 is a block diagram illustrating the configuration of a comparison unit and an amplification unit of the auto gain control unit according to an exemplary embodiment;

FIG. 4 is a block diagram illustrating the configuration of a comparison unit and an amplification unit of the auto gain control unit according to another exemplary embodiment; and

FIG. 5 is a flowchart illustrating a method for processing an audio signal of an auto gain control unit according to an exemplary embodiment.

### DETAILED DESCRIPTION OF EXEMPLARY EMBODIMENTS

Hereinafter, exemplary embodiments are described in detail with reference to the accompanying drawings.

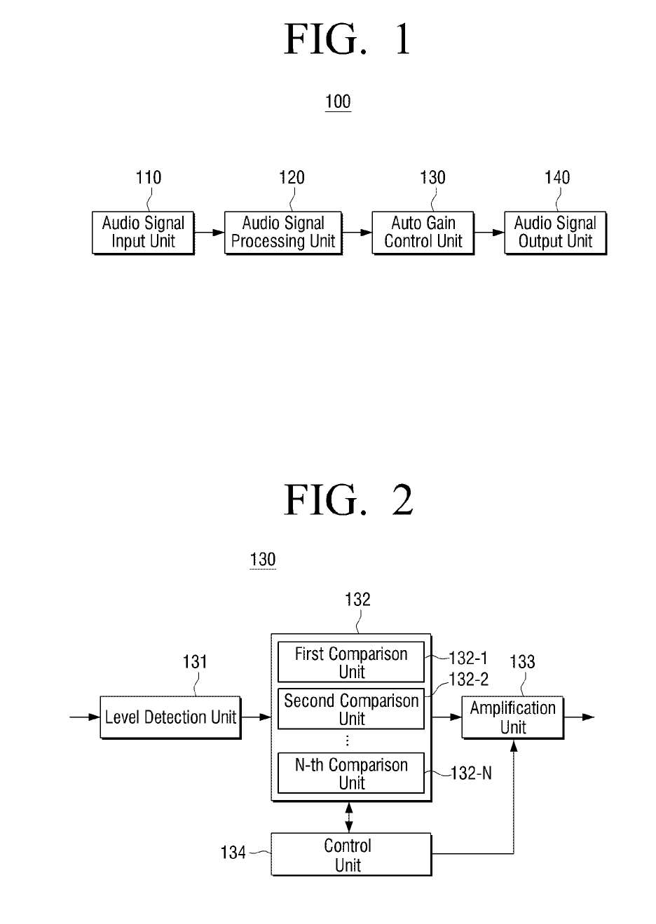

FIG. 1 is a block diagram illustrating the configuration of an audio signal output apparatus according to an exemplary embodiment. As illustrated in FIG. 1, an audio signal output apparatus 100 includes an audio signal input unit 110, an audio signal processing unit 120, an auto gain control unit 130, and an audio signal output unit 140. In an exemplary embodiment, the audio signal output apparatus 100 may be a home theater system. However, this is merely exemplary, and diverse electronic apparatuses that output audio signals may be adopted. The term “unit” as used herein means a hardware component, such as a processor or circuit, and/or a software component that is executed by a hardware component such as a processor.

The audio signal input unit 110 receives audio signals which are transmitted from diverse sources. In particular, the audio signal input unit 110 receive audio data that is compressed by a compression system, such as AC3 (Audio Codin-3), DTS (Digital Theater System), MPEG (Moving Picture Experts Group), or Dolby rue HD.

The audio signal processing unit 120 processes the audio data input through the audio signal input unit 110. Specifically, the audio signal processing unit 120 decodes the compressed audio data and outputs audio data of an uncompressed format. Further, the audio signal processing unit 120 converts the decoded audio data into an analog audio signal.

The auto gain control unit 130 adjusts a gain of an amplifier included in the auto gain control unit and amplifies the audio signal to a predetermined level in order to control the output level of the audio signal processed by the audio signal processing unit 120.

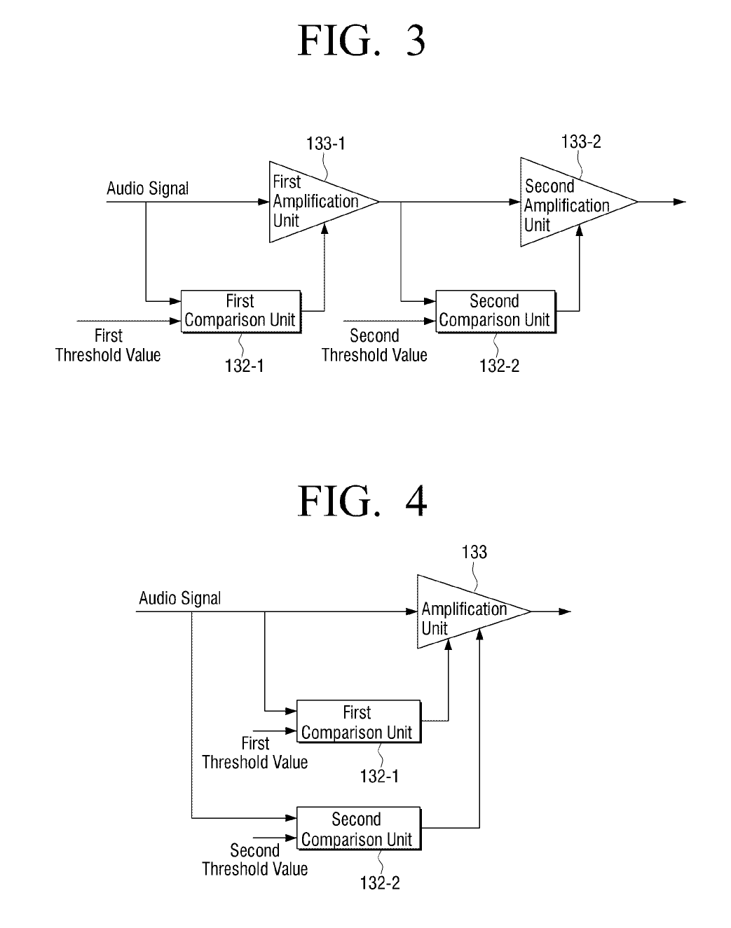

Further, the auto gain control unit 130 outputs the amplified audio signal to the predetermined level. Particularly, in order to prevent the possible damage of the audio signal output apparatus 100 in the case where the input audio signal is directly output, or in the case where the audio signal output apparatus 100 is damaged, or the audio signal having a specified level is output for a continuous time, the auto gain control unit 130 compares the input audio signal with a plurality of threshold values, and adjusts the gain of the amplifier according to the result of the comparison. The features of the auto gain control unit 130 will be described in detail later with reference to FIGS. 3 to 5.

The audio signal output unit 140 outputs the analog audio signal output from the auto gain control unit 130 as sound. In this example, the audio signal output unit 140 may be implemented by a speaker.

On the other hand, although FIG. 1 illustrates that the audio signal input unit 110, the audio signal processing unit 120, the auto gain control unit 130, and the audio signal output unit 140 may be configured as one block. Of course, this is merely exemplary, and the audio signal input unit 110, the audio signal processing unit 120, the auto gain control unit 130, and the audio signal output unit 140 may be implemented by different devices. For example, the audio signal input unit 110 and the audio signal processing unit 120 may be arranged in a DVD player, and the auto gain control unit 130 and the audio signal output unit 140 may be arranged on the speaker that is connected to the DVD player by wire or wirelessly.

Hereinafter, with reference to FIGS. 2 to 4, the auto gain control unit 130 according to diverse exemplary embodiments will be described in detail.

FIG. 2 is a block diagram illustrating the configuration of an auto gain control unit included in the audio signal output apparatus according to an exemplary embodiment. As illustrated in FIG. 2, the auto gain control unit 130 includes a level detection unit 131, a plurality of comparison units 132, an amplification unit 133, and a control unit 143.

The level detection unit 131 detects the output level of the analog audio signal.

The plurality of comparison units 132 repeatedly compares the output level of the analog audio signal detected by the level detection unit 131 with a plurality of preset threshold values. Specifically, the first comparison unit 132-1 compares the output level of the analog audio signal detected by the level detection unit 131 with the first threshold value. Further, a second comparison unit 132-1 compares the output level of the analog audio signal detected by the level detection unit 131 with the second threshold value. In the same manner, the N-th comparison unit 132-N compares the output level of the analog audio signal detected by the level detection unit 131 with the N-th threshold value. In this case, the plurality of comparison units 132 may be implemented by two or more comparators.

Under the control of the control unit 124, the amplification unit 133 amplifies the audio signal so that the audio signal has the output level of a predetermined size through adjustment of a gain that is multiplied by the output level of the audio signal. In this case, the amplification unit may be implemented by one amplifier or a plurality of amplifiers that correspond to the plurality of comparison units 132.

The control unit 134 controls the output level of the audio signal through adjustment of the gain of the amplification unit 133 according to the result of the comparison.

Specifically, the control unit 134 controls the gain of the amplification unit 133 according to the result of the comparison by the first comparison unit 132-1 that compares the output level of the analog audio signal detected by the level detection unit 131 with the first threshold value. That is, if the level of the audio signal exceeds the first threshold value, the control unit 134 adjusts the gain of the amplification unit 133 so as to reduce the output level of the audio signal, and if the level of the audio signal is equal to or lower than the first threshold value, the control unit 134 adjusts the gain of the amplification unit 133 so as to maintain the output level of the audio signal. For example, if the output level of the input audio signal is 110 and the first threshold value is 100, the control unit 134 may adjust the gain of the amplification unit 133 so that the output level of the input audio signal becomes 90. However, if the output level of the input audio signal is 70 and the first threshold value is 100, the control unit 134 may adjust the gain of the amplification unit 133 so that the output level of the input audio signal maintains 70.

In this case, the first threshold value is an output value of the audio signal for which an error occurs in the audio signal output apparatus 100 if the audio signal having the first threshold value is directly output without being controlled by the auto gain control unit 130.

Further, the control unit 134 adjusts the gain of the amplification unit 133 by determining whether the output level of the analog audio signal detected by the level detection unit 131 exceeds the second threshold value for a first preset time.

That is, if the level of the audio signal exceeds the second threshold value for the first preset time, the control unit 134 adjusts the gain of the amplification unit 133 so as to reduce the output level of the audio signal, while if the level of the audio signal is equal to or lower than the second threshold value, the control unit 134 adjust the gain of the amplification unit 133 so as to maintain the output level of the audio signal. For example, if the output level of the input audio signal is 90 and the first threshold value is 80, the control unit 134 may adjust the gain of the amplification unit 133 so that the output level of the input audio signal becomes 70. However, if the output level of the input audio signal is 75 and the first threshold value is 80, the control unit 134 may adjust the gain of the amplification unit 133 so that the output level of the input audio signal maintains 75. In this case, the second threshold value is an output value of the audio signal for which an error occurs in the audio signal output apparatus 100 if the audio signal having the second threshold value is output for the first preset time.

The control unit 134 can adjust the output level of the audio signal according to the result of repeated comparison by the plurality of comparison units at time intervals preset as described above. For example, the control unit 134 may control the output of the audio signal by adjusting the gain of the amplification unit 133 according to the result of the comparison by the third comparison unit 132-3 having a third threshold value for a second preset time.

As described above, by controlling the output level of the audio signal according to the result of the comparison by the plurality of comparison units 132, the output range of the audio signal output apparatus 100 can be maintained in a safe range even if time elapses.

FIG. 3 is a block diagram illustrating the configuration of a comparison unit and an amplification unit of the auto gain control unit according to an exemplary embodiment.

Specifically, as illustrated in FIG. 3, the auto gain control unit 130 includes a first amplifier 133-1 amplifying the input audio signal, and a second amplifier 133-2 connected in series to a rear end of the first amplifier 133-1, a first comparison unit 132-1 comparing the level of the audio signal input to the first amplifier 133-1 with the first threshold value, and a second comparison unit 132-2 comparing the level of the audio signal output from the first amplifier 133-1 with the second threshold value.

In this case, the control unit 134 adjusts the gain of the first amplifier 133-1 in accordance with the result of the comparison by the first comparison unit 132-1, and adjusts the gain of the second amplifier 133-2 in accordance with the result of the comparison by the second comparison unit 132-2.

Specifically, if the level of the audio signal input to the first amplifier 133-1 exceeds the first threshold value, the control unit 134 adjusts the gain of the first amplifier 133-1 so as to reduce the level of the audio signal output from the first amplifier 133-1, while if the level of the audio signal input to the first amplifier 133-1 is equal to or lower than the first threshold value, the control unit 134 adjusts the gain of the first amplifier 133 so as to maintain the level of the audio signal output from the first amplifier 133-1.

Further, the control unit 134 controls the second comparison unit 132-2 to compare the output level of the first amplifier 133-1 with the second threshold value. Specifically, if the output level of the first amplifier 133-1 exceeds the second threshold value for the preset time, the control unit 134 adjusts the gain of the second amplifier 133-2 so as to reduce the level of the audio signal output from the second amplifier 133-2, while if the output level of the first amplifier 133 is equal to or lower than the second threshold value for the preset time, the control unit 134 adjusts the gain of the second amplifier 133-2 so as to maintain the level of the audio signal output from the first amplifier 133-1.

As described above, it is assumed that two comparison units 132-1 and 132-2 are provided, and two amplification units 133-1 and 133-2 are connected in series thereto. However, this is merely exemplary, and the technical feature can be applied even in the case where three or more comparison units are provided, and three or more amplification units are connected in series thereto.

FIG. 4 is a block diagram illustrating the configuration of a comparison unit and an amplification unit of the auto gain control unit according to another exemplary embodiment.

As illustrated in FIG. 4, the auto gain control unit 130 includes an amplification unit 133 amplifying the input audio signal, a first comparison unit 132-1 comparing the level of the audio signal input to the amplification unit 133 with the first threshold value, and a second comparison unit 132-2 connected in parallel to the first comparison unit 132-1 to compare the level of the audio signal input to the amplification unit 133 with the second threshold value.

If the analog signal processed by the audio signal processing unit 120 is input, the control unit 134 controls the first comparison unit 132-1 to compare the level of the audio signal input tot eh amplification unit 133 with the first threshold value. Further, if the level of the audio signal input to the amplification unit 133 exceeds the first threshold value, the control unit 134 adjusts the gain of the amplification unit 133 so as to reduce the level of the audio signal output from the amplification unit 133, while if the level of the audio signal input to the amplification unit 133 is equal to or lower than the first threshold value, the control unit 134 adjust the gain of the amplification unit 133 so as to maintain the output level of the amplification unit 133.

Then, the control unit 134 controls the second comparison unit 132-2 to compare the level of the audio signal input to the amplification unit 133 with the second threshold value.

Then, if the level of the audio signal input to the amplification unit 133 exceeds the second threshold value for the preset time, the control unit 134 controls the gain of the amplification unit 133 so as to reduce the level of the audio signal output from the amplification unit 133, while if the level of the audio signal input to the amplification unit 133 is equal to or lower than the second threshold value for the preset time, the control unit 134 adjusts the gain of the amplification unit 133 so as to maintain the level of the audio signal output from the amplification unit 133.

Although it is assumed that two comparison units 132-1 and 132-2 are connected in parallel as described above, this is merely exemplary, and other exemplary embodiments may include the case where three or more comparison units are provided, and three or more amplification units are connected in parallel thereto.

On the other hand, the circuit configuration described in FIGS. 3 and 4 can be implemented into one chip, and thus as a whole, the main circuit board for processing the audio signal of the audio apparatus can be implemented with a small area.

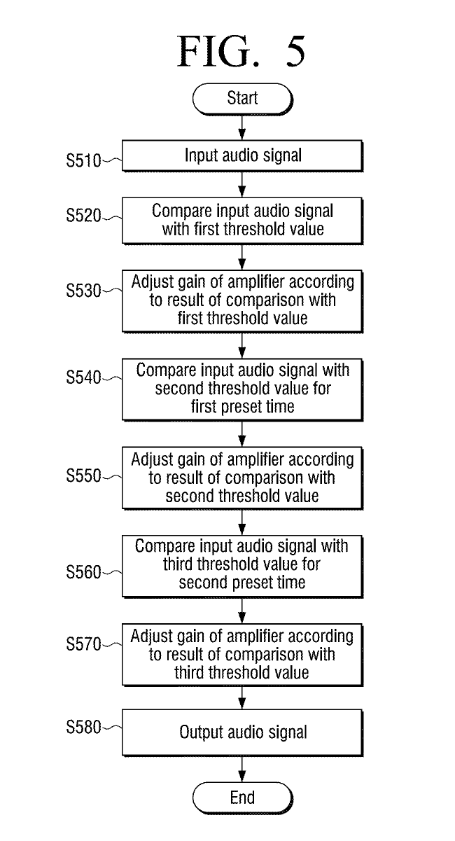

Hereinafter, with reference to FIG. 5, a method for processing an audio signal of an audio signal output apparatus 100 will be described. FIG. 5 is a flowchart illustrating a method for processing an audio signal of an auto gain control unit according to an exemplary embodiment.

First, an audio signal is input to the auto gain control unit 130 (S510). At this time, the input audio signal may be a decoded analog audio signal.

If the audio signal is input, the auto gain control unit 130 compares the input audio signal with the first threshold value (S520). Further, the auto gain control unit 130 adjusts the gain of the amplifier included in the auto gain control unit 130 according to the result of the comparison of the input audio signal with the first threshold value (S530). At this time, the first threshold value is an output value of the audio signal for which an error occurs in the audio signal output apparatus 110 if the audio signal is directly output without being controlled by the auto gain control unit 130.

Specifically, if the level of the input audio signal exceeds the first threshold value, the auto gain control unit 130 adjusts the gain of the amplification unit 133 so as to reduce the output level of the audio signal, while if the level of the input audio signal is equal to or lower than the first threshold value, the auto gain control unit 130 adjusts the gain of the amplification unit 133 so as to maintain the output level of the audio signal.

Further, the auto gain control unit 130 compares the input audio signal with the second threshold value for the first preset time (S540). Then, the auto gain control unit 130 adjusts the gain of the amplifier included in the auto gain control unit 130 according to the result of the comparison of the input audio signal with the second threshold value (S550). At this time, the first threshold value is an output value of the audio signal for which an error occurs in the audio signal output apparatus if the audio signal is output for the first preset time. Further, the second threshold value may be a value that is smaller than the first threshold value.

Specifically, if the level of the input audio signal exceeds the second threshold value for the first preset time, the auto gain control unit 130 adjusts the gain of the amplification unit 133 so as to reduce the output level of the audio signal, while if the level of the audio signal is equal to or lower than the second threshold value for the first preset time, the auto gain control unit 130 adjusts the gain of the amplification unit 133 so as to maintain the output level of the audio signal.

Further, the auto gain control unit 130 compares the input audio signal with the third threshold value for the second preset time (S560). Then, the auto gain control unit 130 adjusts the gain of the amplifier included in the auto gain control unit 130 according to the result of the comparison of the input audio signal with the third threshold value (S570). At this time, the fourth threshold value is an output value of the audio signal for which an error occurs in the audio signal output apparatus if the audio signal is output for the second preset time. Further, the third threshold value may be a value that is smaller than the second threshold value.

Specifically, if the level of the input audio signal exceeds the third threshold value for the second preset time, the auto gain control unit 130 adjusts the gain of the amplification unit 133 so as to reduce the output level of the audio signal, while if the level of the audio signal is equal to or lower than the third threshold value for the second preset time, the auto gain control unit 130 adjusts the gain of the amplification unit 133 so as to maintain the output level of the audio signal.

Then, the auto gain control unit 130 outputs the amplified audio signal according to the gain adjusted through the above-described process (S580).

As described above, according to various exemplary embodiments, not only the maximum output can be limited as in the related art, but also the output of the audio signal can be limited even if the audio signal, which has a level that is lower than the maximum, but causes the apparatus to deteriorate, continues to be output over a specified time, the audio signal output apparatus may deteriorate or a speaker may be damaged, thereby protecting the audio signal output apparatus.

On the other hand, although in this example the input audio signal is compared with three threshold values, this is merely exemplary. Other exemplary embodiments may include the case where the input audio signal is compared with two or four or more threshold values.

While the inventive concept has been shown and described with reference to certain exemplary embodiments thereof, it will be understood by those skilled in the art that various changes in form and detail may be made therein without departing from the spirit and scope of defined by the appended claims.

What is claimed is:

1. An audio signal output apparatus comprising:
an amplification unit which receives and amplifies an audio signal;
a plurality of comparison units which performs comparisons of input levels of the audio signal with different threshold values; and
a control unit which controls an output of the audio signal by changing a gain of the amplification unit in accordance with results of the comparisons performed by the plurality of comparison units.

2. The audio signal output apparatus as claimed in claim 1, wherein the amplification unit comprises a plurality of amplifiers, which are equal in number to a number of the comparison units having the different threshold values, and
wherein the control unit adjusts gains of each of the plurality of amplifiers in accordance with results of the comparisons performed by the plurality of comparison units.

3. The audio signal output apparatus as claimed in claim 2, wherein the amplification unit comprises:
a first amplifier which amplifies the audio signal; and
a second amplifier connected in series to the first amplifier,
wherein the plurality of comparison units comprise:
a first comparison unit which performs a comparison of an input level of the audio signal, which is input to the first amplifier, with a first threshold value; and
a second comparison unit which performs a comparison of an output level of the first amplifier, with a second threshold value,
wherein the control unit adjusts a gain of the first amplifier in accordance with a result of the comparison performed by the first comparison unit and adjusts a gain of the second amplifier in accordance with a result of the comparison performed by the second comparison unit.

4. The audio signal output apparatus as claimed in claim 3, wherein the control unit adjusts the gain of the first amplifier so as to reduce the output level of the first amplifier if the input level of the audio signal input to the first amplifier exceeds the first threshold value, and adjusts the gain of the first amplifier so as to maintain the output level of the first amplifier if the input level of the audio signal input to the first amplifier is equal to or lower than the first threshold value, and
wherein the control unit controls the second comparison unit to compare the output level of the first amplifier with the second threshold value for a preset time.

5. The audio signal output apparatus as claimed in claim 4, wherein the control unit adjusts the gain of the second amplifier so as to reduce an output level of the second amplifier if the output level of the first amplifier exceeds the second threshold value for the preset time, and adjusts the gain of the second amplifier so as to maintain the output level of the first amplifier if the output level of the first amplifier is equal to or lower than the second threshold value.

6. The audio signal output apparatus as claimed in claim 1, wherein each of the plurality of comparison units comprises:
a first comparison unit which compares an input level of the audio signal, which is input to the amplification unit, with a first threshold value; and
a second comparison unit, which is connected in parallel to the first comparison unit, and which compares the input level of the audio signal input to the amplification unit with a second threshold value.

7. The audio signal output apparatus as claimed in claim 6, wherein the control unit adjusts the gain of the amplification unit so as to reduce an output level of the amplification unit if the input level of the audio signal input to the amplification unit exceeds the first threshold value, and adjusts the gain of the amplification unit so as to maintain the output level of the amplification unit if the input level of the audio signal input to the amplification unit is equal to or lower than the first threshold value, and
wherein the control unit controls the second comparison unit to compare the output level of the amplification unit with the second threshold value for a preset time.

8. The audio signal output apparatus as claimed in claim 7, wherein the control unit adjusts the gain of the amplification unit so as to reduce the output level of the amplification unit if the input level of the audio signal input to the amplification unit exceeds the second threshold value for the preset time, and adjusts the gain of the amplification unit so as to maintain the output level of the amplification unit if the input level of the audio signal input to the amplification unit is equal to or lower than the second threshold value.

9. The audio signal output apparatus as claimed in claim 1, wherein the first threshold value is an output value of the audio signal for which a first error occurs in the audio signal output apparatus if the audio signal having the first threshold value is output, and
wherein the second threshold value is an output value of the audio signal for which a second error occurs in the audio signal output apparatus if the audio signal having the second threshold value is output for a preset time.

10. A method for processing an audio signal of an audio signal output apparatus, the method comprising:
comparing a first input level of an audio signal, which is input to a first amplifier included in the audio signal output apparatus, with a first threshold value;
comparing a second input level of the audio signal, which is input to a second amplifier included in the audio signal output apparatus, with a second threshold value for a first preset time; and
outputting the audio signal by adjusting a gain of one of the first amplifier and the second amplifier based on the comparing of the first input level of an audio signal with the first threshold value and the second input level of the audio signal with the second threshold value.

11. The method for processing an audio signal as claimed in claim 10, wherein the outputting of the audio signal comprises adjusting the gain of the first amplifier so as to reduce an output level of the first amplifier if the first input level of the audio signal input to the first amplifier exceeds the first threshold value, and adjusting the gain of the first amplifier so as to maintain the output level of the first amplifier if the first input level of the audio signal input to the first amplifier is equal to or lower than the first threshold value.

12. The method for processing an audio signal as claimed in claim 11, wherein the outputting of the audio signal comprises adjusting the gain of the second amplifier so as to reduce an output level of the second amplifier if the second input level of the audio signal input to the second amplifier exceeds the second threshold value for the first preset time, and adjusting the gain of the second amplifier so as to maintain the output level of the second amplifier if the second input level of the audio signal input to the second amplifier is equal to or lower than the second threshold value.

13. The method for processing an audio signal as claimed in claim 10, wherein the method further comprises comparing a third input level of the audio signal, which is input to a third amplifier included in the audio signal output apparatus, with a third threshold value for a second preset time;
wherein the outputting of the audio signal comprises adjusting a gain of the third amplifier so as to reduce an output level of the third amplifier if the third input level of the audio signal input to the third amplifier exceeds the third threshold value for the second preset time, and adjusting the gain of the third amplifier so as to maintain the output level of the third amplifier if the third input level of the audio signal input to the third amplifier is equal to or lower than the third threshold value.

14. The method for processing an audio signal as claimed in claim 10, wherein the first threshold value is a first output value of the audio signal for which a first error occurs in the audio signal output apparatus if the audio signal having the first threshold value is output, and
wherein the second threshold value is a second output value of the audio signal for which a second error occurs in the audio signal output apparatus if the audio signal having the second threshold value is output for the first preset time.

15. An audio signal output apparatus comprising:
an amplification unit comprising m amplifiers which respectively receive and amplify an input audio signal;
a comparison unit comprising n comparators which respectively perform comparisons of input levels of the input audio signal with different threshold values; and
a control unit which controls an output of the input audio signal by controlling a change of a gain of the amplification unit in accordance with results of the comparisons performed by the n comparators,
wherein m is an integer that is equal to or greater than 1, and n is an integer that is equal to or greater than 2.

16. The audio signal output apparatus as claimed in claim 15, wherein m equals 1,
wherein the n comparison units are connected in parallel to each other and receive the input audio signal as input, and
wherein the control unit adjusts the gain of the amplification unit in accordance with the results of the comparisons performed by the n comparison units.

17. The audio signal output apparatus as claimed in claim 15, wherein m is greater than or equal to 2,
wherein the n comparators of the comparison unit are respectively connected to the m amplifiers of the amplification unit and respectively receive the input audio signal,
wherein a second comparator receives an output signal of an amplifier connected to a first comparator and compares an input level of the received input audio signal with the different threshold values, and
wherein the control unit adjusts gains of the respective amplifiers in accordance with the results of the comparisons by the comparators of the comparison unit, including the comparing performed by the second comparator.

18. An audio signal output apparatus comprising:
at least one amplification unit which receives and amplifies an input audio signal;
a first comparison unit which compares a first input audio signal with a first threshold value;
a second comparison unit which compares a second input audio signal with a second threshold value and a preset time; and
a control unit which changes a gain of the at least one amplification unit based on at least one of the comparing performed by the first comparison unit and the comparing performed by the second comparison unit.

19. The audio signal output apparatus as claimed in claim 18, wherein the first input audio signal is the second input audio signal.

20. The audio signal output apparatus as claimed in claim 18, wherein the comparison units are connected in parallel.
